(19) United States
(12) Patent Application Publication
(10) Pub. No.: US 2026/0333906 A1
(43) Pub. Date: Oct. 22, 2026

(54) PHOTOELECTRIC CONVERSION DEVICE, PHOTOELECTRIC CONVERSION SYSTEM, MOVABLE OBJECT, AND EQUIPMENT

(71) Applicant: CANON KABUSHIKI KAISHA, Tokyo (JP)

(72) Inventors: HIROMASA TSUBOI, Tokyo (JP); YUSUKE ONUKI, Kanagawa (JP)

(21) Appl. No.: 19/636,101

(22) Filed: Apr. 1, 2026

(30) Foreign Application Priority Data
Apr. 17, 2025 (JP) 2025-068332

(51) Int. Cl. H10F 39/00; G06T 7/55; H04N 25/77; H04N 25/79

(52) U.S. Cl. CPC H10F 39/80373; G06T 7/55; H04N 25/77; G06T 2207/30252; H04N 25/79

(57) ABSTRACT

A photoelectric conversion device includes first and second photoelectric conversion units, a first transistor transferring charge of the first photoelectric conversion unit to a first node, a second transistor transferring charge of the second photoelectric conversion unit to the first node, a third transistor resetting the first node, and a fourth transistor switching a capacitance of the first node. A gate electrode of the first transistor is arranged between the first photoelectric conversion unit and gate electrodes of the third and fourth transistors. A gate electrode of the second transistor is arranged between the second photoelectric conversion unit and gate electrodes of the third and fourth transistors. The gate electrodes of the third and fourth transistors face the gate electrodes of the first and second transistors.

### BACKGROUND

### Field of the Technology

The present disclosure relates to a photoelectric conversion device, a photoelectric conversion system, a movable object, and an equipment.

### Description of the Related Art

Japanese Patent Laid-Open No. 2010-103667 describes a solid-state imaging device in which some elements of a pixel circuit are shared by a plurality of pixels.

However, in the solid-state imaging device described in Japanese Patent Laid-Open No. 2010-103667, noise generated due to driving of transistors constituting the pixel circuit is not necessarily sufficiently considered, and there is a possibility that a noise component superimposed on an output signal is not sufficiently suppressed.

### SUMMARY

The present disclosure is directed to provide a technique for reducing the influence of noise generated due to driving of transistors constituting a pixel circuit in a photoelectric conversion device configured to share some elements of the pixel circuit by a plurality of pixels.

According to one disclosure of the present specification, there is provided a photoelectric conversion device including a first photoelectric conversion unit and a second photoelectric conversion unit each configured to generate charge according to incidence of light, a first transistor configured to transfer charge held by the first photoelectric conversion unit to a first node, a second transistor configured to transfer charge held by the second photoelectric conversion unit to the first node, a third transistor configured to reset a voltage of the first node, and a fourth transistor configured to switch a capacitance value of a capacitor coupled to the first node, wherein a gate electrode of the first transistor is arranged between the first photoelectric conversion unit and a gate electrode of the third transistor, wherein a gate electrode of the second transistor is arranged between the second photoelectric conversion unit and the gate electrode of the third transistor, wherein the gate electrode of the third transistor faces the gate electrode of the first transistor and the gate electrode of the second transistor, wherein the gate electrode of the first transistor is arranged between the first photoelectric conversion unit and a gate electrode of the fourth transistor, wherein the gate electrode of the second transistor is arranged between the second photoelectric conversion unit and the gate electrode of the fourth transistor, and wherein the gate electrode of the fourth transistor faces the gate electrode of the first transistor and the gate electrode of the second transistor.

Also, according to another aspect of the present specification, there is provided a photoelectric conversion device including an insulator isolation portion defining a plurality of active regions in a first face of a semiconductor layer, a first photoelectric conversion unit arranged in a first active region of the plurality of active regions and configured to generate charge according to incidence of light, a second photoelectric conversion unit arranged in a second active region of the plurality of active regions and configured to generate charge according to incidence of light, a first transistor arranged in the first active region and configured to transfer charge of the first photoelectric conversion unit to a first node, a second transistor arranged in the second active region and configured to transfer charge of the second photoelectric conversion unit to the first node, and a third transistor arranged in a third active region of the plurality of active regions and configured to reset a voltage of the first node, wherein a gate electrode of the first transistor is arranged between the first photoelectric conversion unit and a gate electrode of the third transistor, wherein a gate electrode of the second transistor is arranged between the second photoelectric conversion unit and the gate electrode of the third transistor, and wherein the gate electrode of the third transistor faces the gate electrode of the first transistor and the gate electrode of the second transistor.

Features of the present disclosure will become apparent from the following description of embodiments with reference to the attached drawings. The following description of embodiments is described by way of example.

### BRIEF DESCRIPTION OF THE DRAWINGS

FIG. 1 is a block diagram illustrating a schematic configuration of a photoelectric conversion device according to a first embodiment.

FIG. 2 is a schematic diagram illustrating a configuration example of the photoelectric conversion device according to the first embodiment.

FIG. 3 is an equivalent circuit diagram illustrating a configuration example of a pixel of the photoelectric conversion device according to the first embodiment.

FIG. 4 is a plan view illustrating a structure of the pixel of the photoelectric conversion device according to the first embodiment.

FIG. 5 is a schematic cross-sectional view illustrating a structure of the pixel of the photoelectric conversion device according to the first embodiment.

FIG. 6 is a plan view illustrating a structure of a pixel of a photoelectric conversion device according to a second embodiment.

FIG. 7 is an equivalent circuit diagram illustrating a configuration example of a pixel of a photoelectric conversion device according to a third embodiment.

FIG. 8 is a plan view illustrating a structure of the pixel of the photoelectric conversion device according to the third embodiment.

FIG. 9 is an equivalent circuit diagram illustrating a configuration example of a pixel of a photoelectric conversion device according to a fourth embodiment.

FIG. 10 is a plan view illustrating a structure of the pixel of the photoelectric conversion device according to the fourth embodiment.

FIG. 11 is a plan view illustrating a structure of a pixel of a photoelectric conversion device according to a fifth embodiment.

FIG. 12 is an equivalent circuit diagram illustrating a configuration example of a pixel of a photoelectric conversion device according to a sixth embodiment.

FIG. 13 is a plan view illustrating a structure of the pixel of the photoelectric conversion device according to the sixth embodiment.

FIG. 14 is a schematic cross-sectional view illustrating a structure of the pixel of the photoelectric conversion device according to the sixth embodiment.

FIG. 15 is a block diagram illustrating a schematic configuration of a photoelectric conversion system according to a seventh embodiment.

FIG. 16A is a diagram illustrating a configuration example of a photoelectric conversion system according to an eighth embodiment.

FIG. 16B is a diagram illustrating a configuration example of a movable object according to the eighth embodiment.

FIG. 17 is a block diagram illustrating a schematic configuration of an equipment according to a ninth embodiment.

### DESCRIPTION OF THE EMBODIMENTS

Hereinafter, embodiments of the present disclosure will be described in detail with reference to the accompanying drawings. The following embodiments are intended to embody the technical idea of the present disclosure and do not limit the technology of the present disclosure. Although a plurality of features is described in the embodiments, not all of the plurality of features are essential to the technology of the present disclosure, and the plurality of features may be arbitrarily combined.

In each of the embodiments described below, devices for imaging purposes will be mainly described as an example of a photoelectric conversion device. However, the embodiments are not limited to the devices for imaging purposes and may be applied to other photoelectric conversion devices. For example, other examples of the photoelectric conversion device include a ranging device (a device for distance measurement and the like using a focus detection or a time of flight (TOF)), a photometric device (a device for measuring the amount of incident light), and the like.

In the following embodiments, connection between elements of a circuit may be described. In this case, even when another element is interposed between the elements of interest, the elements of interest are treated as being connected to each other unless otherwise specified. For example, it is assumed that an element A is connected to one node of a capacitor C having a plurality of nodes, and an element B is connected to the other node of the capacitor. Even in such a case, the element A and the element B are regarded as being connected to each other unless otherwise specified.

In the following description, a term indicating a specific direction or position (for example, “up”, “down”, “right”, “left” and other terms including those terms) is used as necessary. The use of these terms is to facilitate understanding of the embodiments with reference to the drawings, and the technical scope of the present disclosure is not limited by the meanings of these terms. In addition, sizes and positional relationships of members illustrated in the drawings may be exaggerated for clarity of description.

### First Embodiment

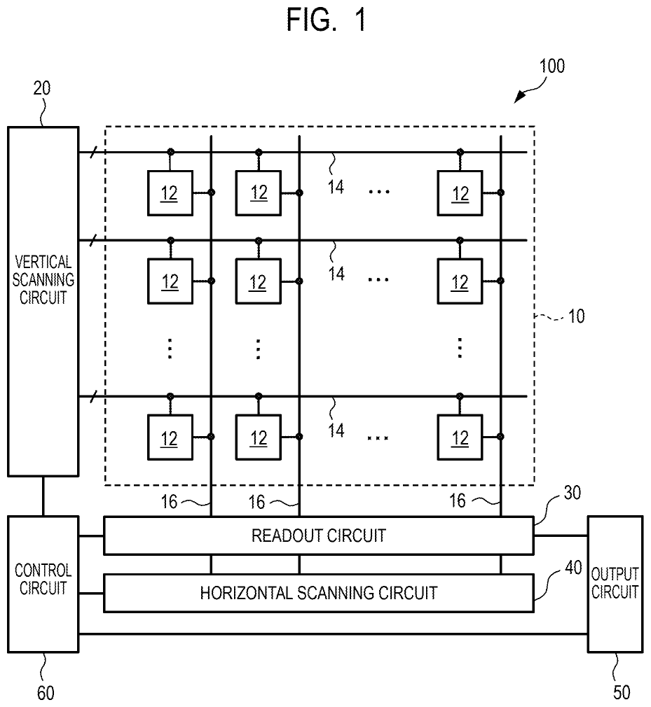

A schematic configuration of a photoelectric conversion device according to a first embodiment will be described with reference to FIG. 1. FIG. 1 is a block diagram illustrating a schematic configuration of a photoelectric conversion device according to the present embodiment.

As illustrated in FIG. 1, the photoelectric conversion device 100 according to the present embodiment includes a pixel array unit 10, a vertical scanning circuit 20, a readout circuit 30, a horizontal scanning circuit 40, an output circuit 50, and a control circuit 60. The pixel array unit 10 is connected to the vertical scanning circuit 20 and the readout circuit 30. The readout circuit 30 is connected to the horizontal scanning circuit 40 and the output circuit 50. The control circuit 60 is connected to the vertical scanning circuit 20, the readout circuit 30, the horizontal scanning circuit 40, and the output circuit 50.

The pixel array unit 10 is provided with a plurality of pixels 12 arranged in a matrix so as to form a plurality of rows and a plurality of columns. Each pixel 12 includes a photoelectric conversion unit including a photoelectric conversion element such as a photodiode and outputs a pixel signal according to the amount of incident light. The number of rows and the number of columns of the pixel array arranged in the pixel array unit 10 are not particularly limited. In addition to effective pixels that output pixel signals according to the amount of incident light, the pixel array unit 10 may include optical black pixels in which photoelectric conversion units are shielded from light, dummy pixels that do not output signals, and the like.

Each row of the pixel array unit 10 is provided with a control line 14 extending in a first direction (lateral direction in FIG. 1). Each of the control lines 14 is connected to the pixels 12 arranged in the first direction in the corresponding row and forms a signal line common to these pixels 12. The first direction in which the control lines 14 extend may be referred to as a row direction or a horizontal direction. Each of the control lines 14 may be constituted by a plurality of signal lines for supplying a plurality of types of control signals to the pixels 12 in the corresponding row. Each of the control lines 14 is connected to the vertical scanning circuit 20.

Each column of the pixel array unit 10 is provided with an output line 16 extending in a second direction (vertical direction in FIG. 1) intersecting the first direction. Each of the output lines 16 is connected to the pixels 12 arranged in the second direction in the corresponding column and forms a signal line common to these pixels 12. The second direction in which the output lines 16 extend may be referred to as a column direction or a vertical direction. Each of the output lines 16 may be constituted by one signal line or may be constituted by a plurality of signal lines. Each of the output lines 16 is connected to the readout circuit 30.

The vertical scanning circuit 20 has a function of generating a control signal for driving the pixels 12 in accordance with a control signal from the control circuit 60. The vertical scanning circuit 20 sequentially supplies the generated control signals to the control lines 14 of the respective rows, thereby performing an operation of driving the plurality of pixels 12 arranged in the pixel array unit 10 in units of rows, that is, so-called vertical scanning. The vertical scanning circuit 20 may be configured using a shift register or an address decoder. Signals read out from the pixels 12 in units of rows by vertical scanning are input to the readout circuit 30 via the output lines 16 of the respective columns.

The readout circuit 30 includes a plurality of column circuits corresponding to each column of the pixel array unit 10 and may have a function of performing predetermined signal processing on the pixel signals output from the pixel array unit 10. Examples of the signal processing on the pixel signal include amplification processing, noise removal processing, addition processing, and A/D (analog-to-digital) conversion processing. The readout circuit 30 may include a column amplifier, a correlation double sampling (CDS) circuit, an addition circuit, an A/D conversion circuit, and the like. The readout circuit 30 may include a signal holding unit for holding the pixel signals of the respective columns received from the pixel array unit 10 or the pixel signals of the respective columns after the signal processing.

The horizontal scanning circuit 40 has a function of generating a control signal for transferring the pixel signals held by the readout circuit 30 to the output circuit 50 in response to a control signal from the control circuit 60. The horizontal scanning circuit 40 sequentially supplies the generated control signals to the signal holding units of the respective columns of the readout circuit 30 to sequentially transfer the pixel signals held by the signal holding units of the respective columns to the output circuit 50, that is, performs so-called horizontal scanning. The horizontal scanning circuit 40 may be configured using a shift register or an address decoder.

The output circuit 50 may include a signal processing circuit that performs predetermined signal processing on the pixel signals sequentially transferred from the readout circuit 30, and an external interface circuit that outputs the processed pixel signals to the outside of the photoelectric conversion device 100. Examples of the signal processing circuit that may be included in the output circuit 50 include a buffer amplifier and a differential amplifier. Examples of the signal processing performed by the output circuit 50 include correction processing by CDS, amplification processing, and high dynamic range (HDR) composition processing. The external interface circuit included in the output circuit 50 is not particularly limited. A serializer/deserializer (SerDes) transmission circuit may be applicable to the external interface circuit. Examples of the SerDes transmission circuit include a low voltage differential signaling (LVDS) circuit and a scalable low voltage signaling (SLVS) circuit.

The control circuit 60 has a function of supplying control signals for controlling operations and timings thereof of the vertical scanning circuit 20, the readout circuit 30, the horizontal scanning circuit 40, and the output circuit 50 to these functional blocks. Some or all of the control signals supplied to the functional blocks may be supplied from the outside of the photoelectric conversion device 100.

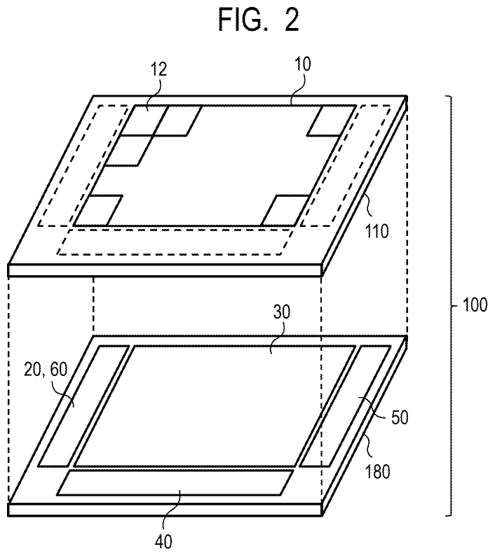

The photoelectric conversion device 100 of the present embodiment may have a configuration in which all the functional blocks described above are arranged on one substrate or may have a configuration in which functional blocks are separately formed on each substrate as a stacked type in which a plurality of substrates is stacked. In the latter case, for example, as illustrated in FIG. 2, the photoelectric conversion device may be configured as a stacked-type photoelectric conversion device in which the pixel substrate 110 and the circuit substrate 180 are stacked and electrically connected to each other.

In the configuration example of FIG. 2, the pixel array unit 10 is arranged on the pixel substrate 110, and other functional blocks are arranged on the circuit substrate 180. By arranging the pixel array unit 10 and the other functional blocks on different substrates, it is possible to reduce the size and increase the functionality of the photoelectric conversion device 100 without sacrificing the area of the pixel array unit 10. The circuit elements constituting one functional block are not necessarily arranged on the same substrate and may be arranged on different substrates.

In the configuration example of FIG. 2, the vertical scanning circuit 20, the horizontal scanning circuit 40, the output circuit 50, and the control circuit 60 are arranged around the pixel array unit 10 so as not to overlap the pixel array unit 10 in a plan view. However, at least a part of the vertical scanning circuit 20, the readout circuit 30, the horizontal scanning circuit 40, the output circuit 50, and the control circuit 60 may overlap the pixel array unit 10 in the plan view. Each of the pixel array unit 10, the vertical scanning circuit 20, the readout circuit 30, the horizontal scanning circuit 40, the output circuit 50, and the control circuit 60 is not necessarily provided on one substrate and may be provided across a plurality of substrates. In this specification, the plan view refers to a plane parallel to a light incident surface of a substrate including a photoelectric conversion unit, as viewed from a normal direction of the plane.

In FIG. 2, a diced chip is assumed as the pixel substrate 110 and the circuit substrate 180, but the pixel substrate 110 and the circuit substrate 180 are not limited to chips. For example, each of the pixel substrate 110 and the circuit substrate 180 may be a wafer. In addition, the pixel substrate 110 and the circuit substrate 180 may be stacked in a wafer state and then diced or may be stacked and bonded after being formed into chips. The number of substrates constituting the stacked-type photoelectric conversion device is not necessarily two and may be three or more.

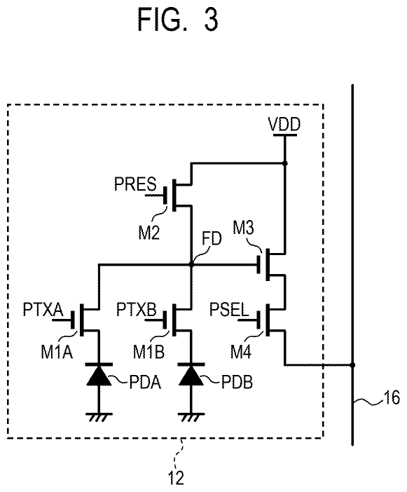

Next, a configuration example of the pixel 12 in the photoelectric conversion device according to the present embodiment will be described with reference to FIG. 3. FIG. 3 is an equivalent circuit diagram illustrating a configuration example of the pixel in the photoelectric conversion device according to the present embodiment.

Each of the pixels 12 included in the pixel array unit 10 may include photoelectric conversion units PDA and PDB, transfer transistors M1A and M1B, a reset transistor M2, an amplifier transistor M3, and a select transistor M4 as illustrated in, e.g., FIG. 3. The photoelectric conversion units PDA and PDB may be constituted by photoelectric conversion elements, for example, photodiodes. The transfer transistors M1A and M1B, the reset transistor M2, the amplifier transistor M3, and the select transistor M4 may be metal-oxide-semiconductor (MOS) transistors. The pixel 12 may include a microlens and a color filter arranged on an optical path until incident light is guided to the photoelectric conversion units PDA and PDB. The microlens has a function of collecting incident light on the photoelectric conversion units PDA and PDB. The photoelectric conversion units PDA and PDB may have separate microlenses corresponding to the photoelectric conversion units PDA and PDB, respectively or may share one microlens. The color filter has a function of selectively transmitting light of a predetermined color.

The photoelectric conversion unit PDA includes an anode connected to a ground voltage node and a cathode connected to a source of the transfer transistor M1A. The photoelectric conversion unit PDB includes an anode connected to the ground voltage node and a cathode connected to a source of the transfer transistor M1B. Drains of the transfer transistors M1A and M1B are connected to a source of the reset transistor M2 and a gate electrode of the amplifier transistor M3. A node FD to which the drains of the transfer transistors M1A and M1B, the source of the reset transistor, and the gate electrode of the amplifier transistor M3 are connected is a so-called floating diffusion. The floating diffusion includes a capacitance component (floating diffusion capacitance) and has a function as a charge holding portion.

A drain of the reset transistor M2 and a drain of the amplifier transistor M3 are connected to a power supply voltage node (voltage VDD). A source of the amplifier transistor M3 is connected to a drain of the select transistor M4. A source of the select transistor M4 is connected to the output line 16. The voltage supplied to the drain of the reset transistor M2 and the voltage supplied to the drain of the amplifier transistor M3 may be the same or different.

Each of the control lines 14 includes four signal lines including a signal line connected to a gate electrode of the transfer transistor M1A, a signal line connected to a gate electrode of the transfer transistor M1B, a signal line connected to a gate electrode of the reset transistor M2, and a signal line connected to a gate electrode of the select transistor M4. The control signal PTXA is supplied from the vertical scanning circuit 20 to the signal line connected to the gate electrode of the transfer transistor M1A. The control signal PTXB is supplied from the vertical scanning circuit 20 to the signal line connected to the gate electrode of the transfer transistor M1B. A control signal PRES is supplied from the vertical scanning circuit 20 to a signal line connected to the gate electrode of the reset transistor M2. A control signal PSEL is supplied from the vertical scanning circuit 20 to the signal line connected to the gate electrode of the select transistor M4. In the case where each transistor is formed of an n-channel transistor, the corresponding transistor is turned on when a high-level control signal is supplied from the vertical scanning circuit 20, and the corresponding transistor is turned off when a low-level control signal is supplied from the vertical scanning circuit 20.

The present embodiment will be described on the assumption that electrons among electron-hole pairs generated in the photoelectric conversion units PDA and PDB by light incidence are used as signal carriers. When electrons are used as the signal carriers, the transistors constituting the pixel 12 may be n-channel MOS transistors. However, the signal carriers are not limited to electrons, and holes may be used as the signal carriers. When holes are used as signal carriers, the conductivity type of each transistor may be opposite to that described in the present embodiment.

Hereinafter, semiconductor regions of the first conductivity type having the same carriers as the signal carriers as the majority carriers is an n-type semiconductor region, and the semiconductor region of the second conductivity type is a p-type semiconductor region. That is, the signal carriers are electrons. The anode and the cathode of the photoelectric conversion unit are of the n-type and the p-type, respectively. Note that the polarity and the conductivity type may all be reversed. That is, the signal carriers may be holes, the semiconductor region of the first conductivity type may be a p-type semiconductor region, and the semiconductor region of the second conductivity type may be an n-type semiconductor region. The anode and the cathode of the photoelectric conversion unit may be p-type and n-type, respectively. In this case, the voltage relationship is also reversed.

The names of the source and the drain of the MOS transistor may vary depending on the conductivity type of the transistor and the function of interest. Some or all of the names of the source and the drain used in the present embodiment may be referred to as reverse names. In this specification, the source and the drain of each terminal of the MOS transistor may be referred to as a main node, and the gate thereof may be referred to as a control node.

The photoelectric conversion units PDA and PDB convert (photoelectrically convert) the incident light into charge of an amount corresponding to the amount of the incident light and accumulate the generated charge. The transfer transistor M1A transfers the charge held by the photoelectric conversion unit PDA to the node FD by turning on in response to the control signal PTXA. Similarly, the transfer transistor M1B transfers the charge held by the photoelectric conversion unit PDB to the node FD by turning on in response to the control signal PTXB. The node FD holds the charge transferred from the photoelectric conversion units PDA and PDB and sets the voltage thereof to a voltage corresponding to the capacitance value of the capacitor coupled thereto (floating diffusion capacitance) and the amount of the transferred charge.

The reset transistor M2 resets the node FD to a voltage corresponding to the voltage VDD by turning on in response to the control signal PRES. At this time, it is also possible to reset the photoelectric conversion units PDA and PDB to voltages corresponding to the voltage VDD by turning on the transfer transistors M1A and M1B. The timing at which the reset transistor M2 is turned off from the on-state in response to the control signal PRES may be the timing of the start of the exposure period of the photoelectric conversion units PDA and PDB. After the charges are transferred from the photoelectric conversion units PDA and PDB to the node FD, the timing at which the transfer transistors M1A and M1B are turned off from the on-state in response to the control signals PTXA and PTXB may be the timing at which the exposure period of the photoelectric conversion units PDA and PDB ends.

The amplifier transistor M3 has the drain to which the voltage VDD is supplied and the source to which a bias current is supplied from a current source (not illustrated) via the select transistor M4 and the output line 16 and constitutes an amplifier unit (source follower circuit) having the gate as an input node. Further, the select transistor M4 connects the amplifier transistor M3 to the signal output line 16 by turning on in response to the control signal PSEL, so that the output of the signal from the amplifier transistor M3 to the output line 16 is enabled (selected state). Accordingly, the amplifier transistor M3 may output the pixel signal corresponding to the voltage of the node FD to the output line 16 via the select transistor M4. That is, the amplifier transistor M3 and the select transistor M4 function as an output unit that outputs a signal according to the voltage of the node FD.

It may be also considered that the pixel circuit of FIG. 3 includes the pixel 12 including the photoelectric conversion unit PDA and the transfer transistor M1A, and the pixel 12 including the photoelectric conversion unit PDB and the transfer transistor M1B. In this case, the pixel 12 including the photoelectric conversion unit PDA and the transfer transistor M1A, and the pixel 12 including the photoelectric conversion unit PDB and the transfer transistor M1B share the node FD, the reset transistor M2, the amplifier transistor M3, and the select transistor M4. For example, the pixel 12 including the photoelectric conversion unit PDA and the transfer transistor M1A, and the pixel 12 including the photoelectric conversion unit PDB and the transfer transistor M1B may be two pixels 12 arranged in adjacent rows of the same column. By applying such a configuration, the number of transistors per photoelectric conversion unit PD in the pixel 12 (the ratio of the number of transistors to the number of photoelectric conversion units PD) may be reduced, and for example, the pixel 12 may be miniaturized.

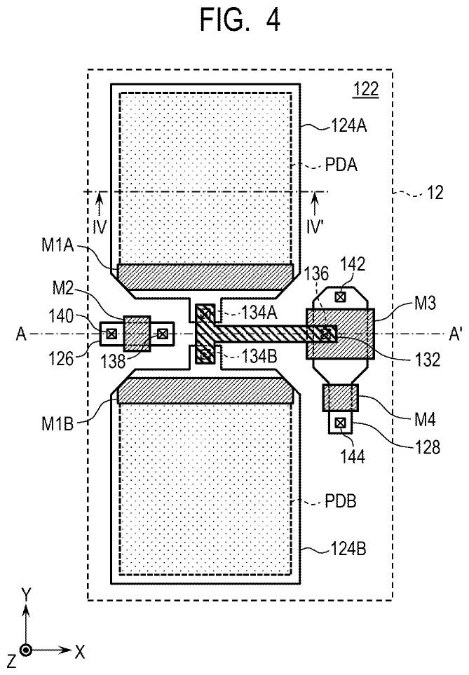

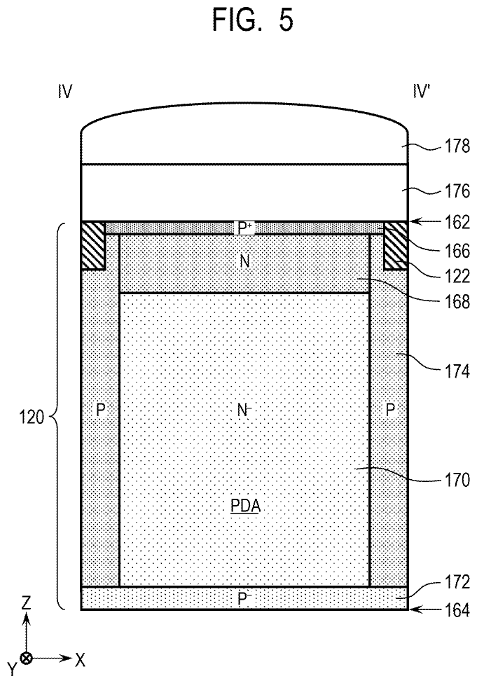

Next, the structure of the pixel 12 in the photoelectric conversion device according to the present embodiment will be described more specifically with reference to FIG. 4 and FIG. 5 by taking a front-illuminated photoelectric conversion device as an example. Here, an example in which the configuration of the present embodiment is applied to a front-illuminated photoelectric conversion device will be described, but the configuration may also be applied to a back-illuminated photoelectric conversion device. Note that the front-illuminated photoelectric conversion device is a photoelectric conversion device configured to detect light incident from the front face side of a semiconductor layer (semiconductor substrate) in which transistors, interconnections, and the like are arranged. The back-illuminated photoelectric conversion device is a photoelectric conversion device configured to detect light incident from the back face side of a semiconductor layer (semiconductor substrate) opposite to a face on which transistors, interconnections, and the like are arranged.

FIG. 4 is a plan view of a semiconductor layer (semiconductor substrate) provided with elements constituting the pixel circuit as viewed from a front face side. In order to simplify the drawings, FIG. 4 illustrates only active regions provided in a semiconductor layer, a polycrystalline silicon layer constituting the gate electrodes of the transistors, and a pattern of a part of interconnections arranged in an upper-level layer than the polycrystalline silicon layer. In FIG. 4, the active region is represented by a white region surrounded by a solid line. The polycrystalline silicon layer is represented by a region surrounded by a solid line and having a diagonal line pattern slanting downward to the left, and the gate electrode of each transistor is denoted by a reference numeral representing the transistor. The interconnection is represented by a region surrounded by a solid line and having a diagonal line pattern slanting downward to the right. In addition, rectangular regions with x-mark indicate a contact plug or a via plug between layers for connecting conductive members. The pixel array unit 10 is configured by repeatedly arranging the unit structures illustrated in FIG. 4 in translational symmetry with respect to the X direction and the Y direction. The X direction may be parallel to the first direction (row direction or horizontal direction), and the Y direction may be parallel to the second direction (column direction or vertical direction).

An insulator isolation portion 122 for defining active regions 124A, 124B, 126 and 128 is provided in the front face (first face) side of a semiconductor layer 120. The insulator isolation portion 122 may be formed by a shallow trench isolation (STI) method, a local oxidation of silicon (LOCOS) method, or the like. The photoelectric conversion unit PDA and the transfer transistor M1A are provided in the active region 124A. In FIG. 4, a region above the gate electrode of the transfer transistor M1A is a source region of the transfer transistor M1A including the cathode of the photoelectric conversion unit PDA, and a region below the gate electrode of the transfer transistor M1A is a drain region of the transfer transistor M1A. The photoelectric conversion unit PDB and the transfer transistor M1B are provided in the active region 124B. In FIG. 4, a region below the gate electrode of the transfer transistor M1B is a source region of the transfer transistor M1B including the cathode of the photoelectric conversion unit PDB, and a region above the gate electrode of the transfer transistor M1B is a drain region of the transfer transistor M1B. The reset transistor M2 is provided in the active region 126. The amplifier transistor M3 and the select transistor M4 are provided in the active region 128.

The active region 124A and the active region 124B are arranged in a direction parallel to the Y direction so that the drain region side of the transfer transistor M1A and the drain region side of the transfer transistor M1B face each other. In one example, the active region 124A and the active region 124B, the gate electrode of the transfer transistor M1A and the gate electrode of the transfer transistor M1B, and the photoelectric conversion unit PDA and the photoelectric conversion unit PDB may be arranged line-symmetrically with respect to an imaginary straight line A-A′ extending in the X direction as a symmetry axis. However, each of the active region 124A and the active region 124B, the gate electrode of the transfer transistor M1A and the gate electrode of the transfer transistor M1B, and the photoelectric conversion unit PDA and the photoelectric conversion unit PDB may not necessarily be arranged in line symmetry. End portions on the gate width direction of the gate electrode of the transfer transistor M1A and end portions on the gate width direction of the gate electrode of the transfer transistor M1B may be located on the insulator isolation portion 122 or may be located on the active regions 124A and 124B.

The active region 126 is arranged between the active region 124A and the active region 124B. The active region 126 has a rectangular shape elongated in the X direction, and the reset transistor M2 is provided in the active region 126 so that the gate length direction thereof is parallel to the X direction. At least a part of the gate electrode of the reset transistor M2 faces the gate electrode of the transfer transistor M1A and the gate electrode of the transfer transistor M1B. In other words, the gate electrode of the transfer transistor M1A is arranged between the photoelectric conversion unit PDA and the gate electrode of the reset transistor M2. The gate electrode of the transfer transistor M1B is arranged between the photoelectric conversion unit PDB and the gate electrode of the reset transistor M2. Note that the fact that the gate electrode of the reset transistor M2 and the gate electrode of the transfer transistor M1A or M1B are opposed to each other means that the gate electrode of the reset transistor M2 and the gate electrode of transfer transistors M1A or M1B are arranged without interposing another conductive member therebetween.

The active region 128 is arranged adjacent to the active regions 124A and 124B in the X direction. The active region 128 has a shape elongated in the Y direction, and the amplifier transistor M3 and the select transistor M4 are provided in the active region 128 so that the gate length direction thereof is parallel to the Y direction. The gate electrode of the amplifier transistor M3 and the gate electrode of the select transistor M4 are arranged over the active region 128 so as to be aligned in the Y direction. A portion of the active region 128 between the gate electrode of the amplifier transistor M3 and the gate electrode of the select transistor M4 is a source region of the amplifier transistor M3 and is also a drain region of the select transistor M4. The gate width of the amplifier transistor M3 is preferably larger than the gate widths of the reset transistor M2 and the select transistor M4 from the viewpoint of improving the current drive capability.

When viewed in the Y direction, the gate electrode of the amplifier transistor M3 is not located between the gate electrode of the transfer transistor M1A and the gate electrode of the transfer transistor M1B. On the other hand, when viewed in the X direction, the gate electrode of the amplifier transistor M3 is located between the gate electrode of the transfer transistor M1A and the gate electrode of the transfer transistor M1B. In other words, the gate electrode of the amplifier transistor M3 overlaps the straight line A-A′ in the plan view but does not overlap the region between the gate electrode of the transfer transistor M1A and the gate electrode of the transfer transistor M1B.

The drain of the transfer transistor M1A is connected to an interconnection 132 via a contact plug 134A. The drain of the transfer transistor M1B is connected to the interconnection 132 via a contact plug 134B. The gate electrode of the amplifier transistor M3 is connected to the interconnection 132 via the via plug 136. Here, the interconnection 132 has a T-shape including a first portion extending in the Y direction and electrically connecting the contact plug 134A and the contact plug 134B, and a second portion extending from the first portion in the X direction and electrically connecting the first portion and the via plug 136. Thus, the drain of the transfer transistor M1A, the drain of the transfer transistor M1B, and the gate electrode of the amplifier transistor M3 are electrically connected to each other via the interconnection 132.

The source region of the reset transistor M2 is electrically connected to the interconnection 132 via the contact plug 138 and an interconnection (not illustrated). The node including the drains of the transfer transistors M1A and M1B, the source of the reset transistor M2, the gate electrode of the amplifier transistor M3, the interconnection 132, and the like is a node FD. The drain region of the reset transistor M2 is supplied with the voltage VDD via an interconnection (not illustrated) and the contact plug 140. The drain region of the amplifier transistor M3 is supplied with the voltage VDD via an interconnection (not illustrated) and the contact plug 142. The source region of the select transistor M4 is connected to the output line 16 via the contact plug 144.

In the present embodiment, the gate electrode of the reset transistor M2, the node FD, and the gate electrode of the amplifier transistor M3 are arranged so as to be aligned in the X direction. On the other hand, of these, only the gate electrode of the amplifier transistor M3 is not located between the gate electrodes of the transfer transistors M1A and M1B. With this arrangement, the parasitic capacitance between the gate electrode of the amplifier transistor M3 and the gate electrodes of the transfer transistors M1A and M1B, that is, the capacitance of the node FD may be reduced, and the conversion efficiency from the charge amount to the voltage in the node FD may be increased.

FIG. 5 is a schematic cross-sectional view illustrating the structure of the photoelectric conversion unit PDA and corresponds to a cross-sectional view taken along line IV-IV′ of FIG. 4. Although only the photoelectric conversion unit PDA is illustrated in FIG. 5, the same applies to the photoelectric conversion unit PDB.

The semiconductor layer 120 provided with the photoelectric conversion units PDA and PDB has a first face 162 on the front face side and a second face 164 on the back face side. The semiconductor layer 120 includes p-type semiconductor regions 166, 172, and 174, n-type semiconductor regions 168 and 170, and an insulator isolation portion 122.

The n-type semiconductor regions 168 and 170 function as the cathode of the photodiode constituting the photoelectric conversion unit PDA. The n-type semiconductor region 168 is arranged on a side of the first face 162 of the semiconductor layer 120, and the n-type semiconductor region 170 is arranged on a side of the second face 164 of the semiconductor layer 120. The n-type semiconductor region 170 serves as a photoelectric conversion region, and the n-type semiconductor region 168 serves to collect signal charge generated in the n-type semiconductor region 170. For these purposes, the peak impurity concentration of the n-type semiconductor region 168 is set higher than the peak impurity concentration of the n-type semiconductor region 170. The p-type semiconductor region 174 is provided on side faces of the n-type semiconductor regions 168 and 170. The p-type semiconductor region 174 has a role as the anode of the photodiode constituting the photoelectric conversion unit PDA and also has a role of isolating adjacent photoelectric conversion units PDA and PDB from each other.

The p-type semiconductor region 166 is provided in contact with the first face 162 of the semiconductor layer 120. The p-type semiconductor region 172 is provided in contact with the second face 164 of the semiconductor layer 120. The p-type semiconductor regions 166 and 172 have a function of suppressing a dark current generated on the first face 162 and the second face 164, respectively. The peak impurity concentration of the p-type semiconductor region 166 is set higher than the peak impurity concentration of the p-type semiconductor region 172. The insulator isolation portion 122 is provided in the surface portion of the first face 162 of the semiconductor layer 120 and has a role of isolating the transistors and the photoelectric conversion units PDA and PDB from each other. The insulator isolation portion 122 is surrounded by p-type semiconductor regions 166 and 174.

Over the first face 162 of the semiconductor layer 120, an interconnection structure layer 176 including the gate layer constituting the gate electrodes of the transistors and the metal interconnection layer is provided. An optical structure layer 178 including the color filters, the microlenses, and the like is provided over the interconnection structure layer 176. A circuit substrate 180 or a support substrate (not illustrated) may be bonded to the second face 164 of the semiconductor layer 120.

As described above, in the present embodiment, the gate electrode of the transfer transistor M1A is arranged between the photoelectric conversion unit PDA and the gate electrode of the reset transistor M2. The gate electrode of the transfer transistor M1B is arranged between the photoelectric conversion unit PDB and the gate electrode of the reset transistor M2. With such an arrangement, it is possible to reduce the influence of the voltage change of the gate electrode of the reset transistor M2 on the photoelectric conversion units PDA and PDB.

That is, when the gate electrode of the reset transistor M2 and the photoelectric conversion units PDA and PDB are opposed to each other, the dark current may increase around the photoelectric conversion units PDA and PDB by turning on the reset transistor M2. Specifically, the electric field from the gate electrode of the reset transistor M2 set to high-level may decrease the hole density at the interface of the portion of the insulator isolation portion 122 facing the n-type semiconductor region 168 and increase the dark current. When the dark current flows into the photoelectric conversion units PDA and PDB, a noise component superimposed on the signal charge may increase.

In this regard, in the present embodiment, since the gate electrodes of the transfer transistors M1A and M1B are arranged between the photoelectric conversion units PDA and PDB and the gate electrode of the reset transistor M2, it is possible to reduce the influence of the voltage change of the gate electrode of the reset transistor M2. For example, in a period in which the photoelectric conversion units PDA and PDB accumulate signal charges, the gate electrodes of the transfer transistors M1A and M1B are held at an off-state voltage. Therefore, even if the reset transistor M2 is turned on during this period, the influence of the voltage change of the gate electrode is blocked by the gate electrodes of the transfer transistors M1A and M1B, and therefore, it is possible to suppress an increase in dark current around the photoelectric conversion units PDA and PDB. Accordingly, noise superimposed on the output signal of the photoelectric conversion device may be reduced.

As described above, according to the present embodiment, in the photoelectric conversion device in which some elements of the pixel circuit are shared by a plurality of pixels, it is possible to reduce the influence of noise generated due to the driving of the transistors constituting the pixel circuit.

### Second Embodiment

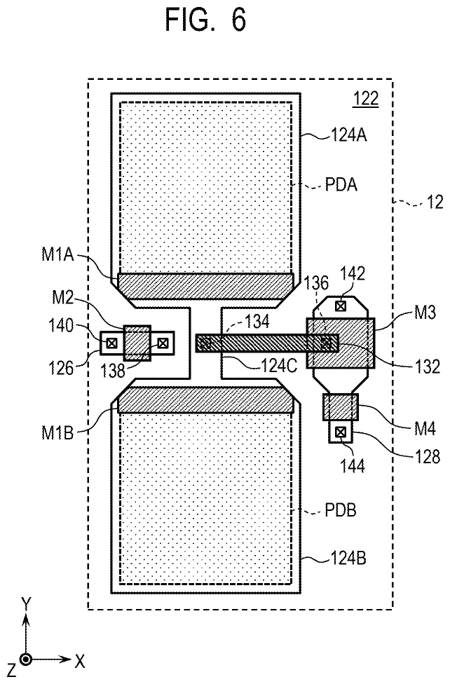

A photoelectric conversion device according to a second embodiment will be described with reference to FIG. 6. The same components as those of the photoelectric conversion device according to the first embodiment are denoted by the same reference numerals, and description thereof will be omitted or simplified.

The photoelectric conversion device according to the present embodiment is the same as the photoelectric conversion device according to the first embodiment except that the configuration of the pixel 12 is different. In the present embodiment, differences from the photoelectric conversion device according to the first embodiment will be mainly described, and description of points similar to those of the photoelectric conversion device according to the first embodiment will be appropriately omitted.

Similarly to FIG. 4, FIG. 6 is a plan view of the semiconductor layer (semiconductor substrate) in which each element constituting the pixel circuit is provided, as viewed from the front face side. In the pixel 12 of the first embodiment, the active region 124A in which the photoelectric conversion unit PDA and the transfer transistor M1A are provided and the active region 124B in which the photoelectric conversion unit PDB and the transfer transistor M1B are provided are independent of each other. In contrast, in the pixel 12 of the present embodiment, the photoelectric conversion units PDA and PDB and the transfer transistors M1A and M1B are provided in one continuous active region 124. That is, in the present embodiment, as illustrated in FIG. 6, the active regions 124A and 124B have a connecting portion 124C that connects the drain region of the transfer transistor M1A and the drain region of the transfer transistor M1B and constitute one continuous active region 124. Other points are the same as those of the pixel 12 of the photoelectric conversion device according to the first embodiment.

According to the layout of the pixel 12 of the present embodiment, the connection between the drain regions of the transfer transistors M1A and M1B and the interconnection 132 may be configured by one contact plug 134, and the interconnection 132 may be configured by a linear pattern extending in the X direction. Accordingly, the length and area of the interconnection 132 may be reduced as compared with the case of the first embodiment, and the capacitance value of the parasitic capacitance of the interconnection 132, that is, the parasitic capacitance coupled to the node FD may be reduced. Therefore, the conversion efficiency from the charge amount to the voltage in the node FD may be increased as compared with the case of the first embodiment.

As described above, according to the present embodiment, the same effects as those of the first embodiment may be obtained, and the conversion efficiency from the charge amount to the voltage in the node FD may be increased.

### Third Embodiment

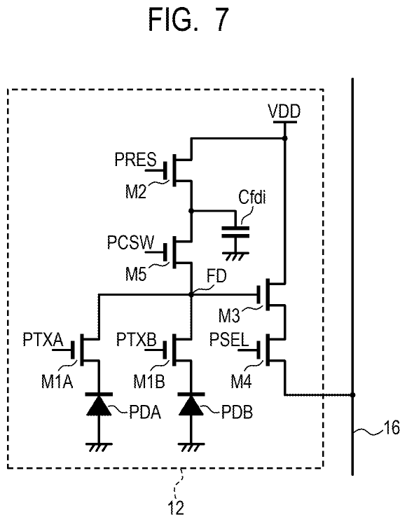

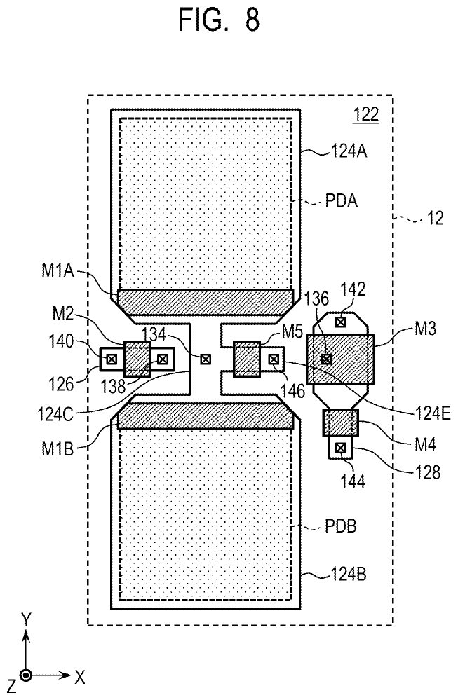

A photoelectric conversion device according to a third embodiment will be described with reference to FIG. 7 and FIG. 8. The same components as those of the photoelectric conversion device according to the first or second embodiment are denoted by the same reference numerals, and description thereof will be omitted or simplified.

The photoelectric conversion device according to the present embodiment is the same as the photoelectric conversion device according to the first or second embodiment except that the configuration of the pixel 12 is different. In the present embodiment, differences from the photoelectric conversion device according to the second embodiment will be mainly described, and description of points similar to those of the photoelectric conversion device according to the first or second embodiment will be appropriately omitted.

FIG. 7 is an equivalent circuit diagram illustrating a configuration example of the pixel 12 in the photoelectric conversion device according to the present embodiment. As illustrated in FIG. 7, the pixel 12 of the present embodiment further includes a capacitance switching transistor M5 and a capacitor Cfdi in addition to the pixel 12 of the first or second embodiment. A source of the capacitance switching transistor M5 is connected to the node FD. A drain of the capacitance switching transistor M5 is connected to the source of the reset transistor M2. One electrode of the capacitor Cfdi is connected to a connection node between the source of the reset transistor M2 and the drain of the capacitance switching transistor M5. The other electrode of the capacitor Cfdi is connected to the ground voltage node.

The connection mode of the capacitance switching transistor M5 and the capacitor Cfdi is not limited to the example of FIG. 7. For example, in the pixel circuit of FIG. 3, the drain of the capacitance switching transistor M5 may be connected to the node FD, the source of the capacitance switching transistor M5 may be connected to one electrode of the capacitor Cfdi, and the other electrode of the capacitor Cfdi may be connected to the ground voltage node.

In the case of the pixel configuration of the present embodiment, the control line 14 of each row may be constituted by a total of five signal lines further including a signal line for supplying the control signal PCSW to a gate electrode of the capacitance switching transistor M5 of the corresponding row. When the capacitance switching transistor M5 is formed of an n-channel transistor, the capacitance switching transistor M5 is turned on when a high-level control signal PCSW is supplied from the vertical scanning circuit 20 and is turned off when a low-level control signal PCSW is supplied from the vertical scanning circuit 20. When the capacitance switching transistor M5 is turned on, the capacitor Cfdi is connected to the node FD, and the capacitance of the node FD increases. As a result, it is possible to reduce the conversion efficiency from the charge to the voltage in the node FD, and it is possible to suppress the whiteout of the image when imaging a bright object.

The capacitor Cfdi is not particularly limited and may be, for example, a parasitic capacitor, a MOS capacitor, a metal-insulator-metal (MIM) capacitor, or a polysilicon-oxide-metal (POM) capacitor.

Similarly to FIG. 4, FIG. 8 is a plan view of the semiconductor layer (semiconductor substrate) in which each element constituting the pixel circuit is provided, as viewed from the front face side. In the present embodiment, the active region 124 further includes an extending portion 124E extending in the X direction from the connecting portion 124C connecting the drain region of the transfer transistor M1A and the drain region of the transfer transistor M1B. A capacitance switching transistor M5 is provided in the extending portion 124E. That is, the drain regions of the transfer transistors M1A and M1B are also a source region of the capacitance switching transistor M5. The capacitance switching transistor M5 is provided in the extending portion 124E of the active region 124 so that the gate length direction thereof is parallel to the X direction. At least a part of the gate electrode of the capacitance switching transistor M5 faces the gate electrode of the transfer transistor M1A and the gate electrode of the transfer transistor M1B. In other words, the gate electrode of the transfer transistor M1A is arranged between the photoelectric conversion unit PDA and the gate electrode of the capacitance switching transistor M5. The gate electrode of the transfer transistor M1B is arranged between the photoelectric conversion unit PDB and the gate electrode of the capacitance switching transistor M5.

The drain regions of the transfer transistors M1A and M1B and the source region of the capacitance switching transistor M5 are electrically connected to the gate electrode of the amplifier transistor M3 via the contact plug 134, an interconnection (not illustrated), and the via plug 136. The drain region of the capacitance switching transistor M5 is electrically connected to the source region of the reset transistor M2 and the capacitor Cfdi via the contact plug 146, an interconnection (not illustrated), the contact plug 138, and the like.

In the present embodiment, the gate electrode of the transfer transistor M1A is arranged between the photoelectric conversion unit PDA and the gate electrode of the capacitance switching transistor M5. The gate electrode of the transfer transistor M1B is arranged between the photoelectric conversion unit PDB and the gate electrode of the capacitance switching transistor M5. By arranging the gate electrode of the capacitance switching transistor M5 in this manner, it is possible to reduce the influence of the voltage change of the gate electrode of the capacitance switching transistor M5, as in the case of the gate electrode of the reset transistor M2 in the first and second embodiments. For example, in a period in which the photoelectric conversion units PDA and PDB accumulate signal charges, the gate electrodes of the transfer transistors M1A and M1B are held at an off-state voltage. Therefore, even if the capacitance switching transistor M5 is turned on during this period, the influence of the voltage change of the gate electrode is blocked by the gate electrodes of the transfer transistors M1A and M1B, and therefore, an increase in dark current around the photoelectric conversion units PDA and PDB may be suppressed.

In the present embodiment, the gate electrode of the reset transistor M2, the gate electrode of the capacitance switching transistor M5, the node FD, and the gate electrode of the amplifier transistor M3 are arranged so as to be aligned in the X direction. On the other hand, of these, only the gate electrode of the amplifier transistor M3 is not located between the gate electrodes of the transfer transistors M1A and M1B. With this arrangement, the parasitic capacitance between the gate electrode of the amplifier transistor M3 and the gate electrodes of the transfer transistors M1A and M1B, that is, the capacitance of the node FD may be reduced, and the conversion efficiency from the charge amount to the voltage in the node FD may be increased.

As described above, according to the present embodiment, even when the pixel 12 further includes the capacitance switching transistor, the same effects as those of the first and second embodiments may be obtained.

### Fourth Embodiment

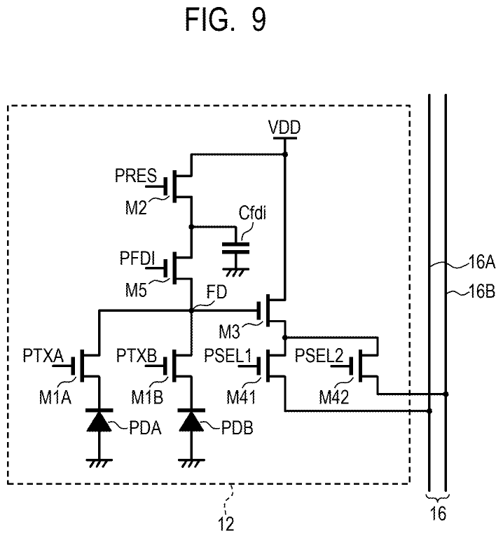

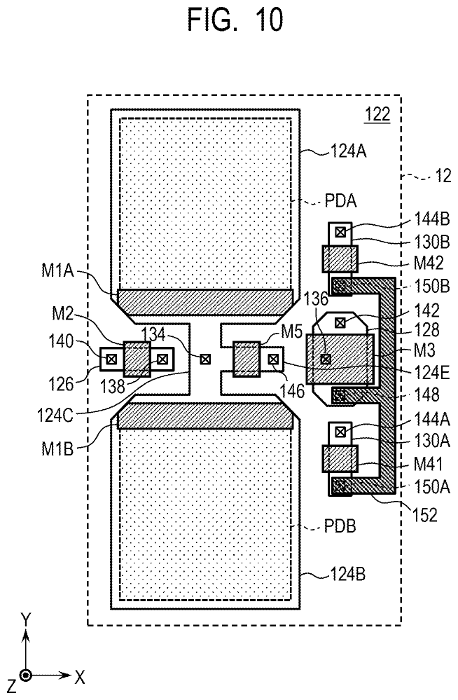

A photoelectric conversion device according to a fourth embodiment will be described with reference to FIG. 9 and FIG. 10. The same components as those of the photoelectric conversion devices according to the first to third embodiments are denoted by the same reference numerals, and description thereof will be omitted or simplified.

The photoelectric conversion device according to the present embodiment is the same as the photoelectric conversion devices according to the first to third embodiments except that the configurations of the pixel 12 and the output line 16 are different. In the present embodiment, differences from the photoelectric conversion device according to the third embodiment will be mainly described, and description of points similar to those of the photoelectric conversion devices according to the first to third embodiments will be appropriately omitted.

FIG. 9 is an equivalent circuit diagram illustrating a configuration example of the pixel 12 in the photoelectric conversion device according to the present embodiment. The pixel 12 of the third embodiment includes the select transistor M4 connected to the source of the amplifier transistor M3. On the other hand, as illustrated in FIG. 9, the pixel 12 of the present embodiment has two select transistors M41 and M42 connected to the amplifier transistor M3. In addition, in the photoelectric conversion device of the present embodiment, the output line 16 arranged in each column of the pixel array unit 10 is constituted by two signal lines 16A and 16B. The drains of the select transistors M41 and M42 are connected to the source of the amplifier transistor M3. The source of the select transistor M41 is connected to the signal line 16A. The source of the select transistor M42 is connected to the signal line 16B. Other points of the pixel 12 of the present embodiment are the same as those of the pixel 12 of the third embodiment. Although an application example to the pixel 12 of the third embodiment will be described here, two select transistors M41 and M42 may be provided for the pixel 12 of the first or second embodiment.

In the case of the pixel configuration of the present embodiment, the control line 14 of each row may be constituted by a total of six signal lines further including two signal lines for supplying control signals PSEL1 and PSEL2 to the gates of the select transistors M41 and M42 instead of the signal line for supplying the control signal SEL. When the select transistors M41 and M42 are formed of n-channel transistors, they are turned on when the control signals SEL1 and SEL2 of high-level are supplied and are turned off when the control signals SEL1 and SEL2 of low-level are supplied. When the select transistor M41 is turned on, a signal corresponding to the voltage of the node FD is output to the signal line 16A, and when the select transistor M42 is turned on, a signal corresponding to the voltage of the node FD is output to the signal line 16B. By configuring the output line 16 of each column with a plurality of signal lines, the signals of the pixels 12 of a plurality of rows may be read out in parallel, and the readout time of the pixel signals from the pixel array unit 10 may be shortened.

Similarly to FIG. 4, FIG. 10 is a plan view of the semiconductor layer (semiconductor substrate) in which each element constituting the pixel circuit is provided, as viewed from the front face side. In the first to third embodiments, the amplifier transistor M3 and the select transistor M4 are arranged in one active region 128. In contrast, in the present embodiment, the amplifier transistor M3 is arranged in the active region 128, the select transistor M41 is arranged in the active region 130A, and the select transistor M42 is arranged in the active region 130B. Like the active regions 128 in the first to third embodiments, the active regions 128, 130A, and 130B may be arranged adjacent to the active regions 124A and 124B in the X direction.

The active region 128 has a shape elongated in the Y direction, and the amplifier transistor M3 is provided in the active region 128 so that the gate length direction thereof is parallel to the Y direction. However, the arrangement of the active region 128 is not limited to this example, and the active region 128 may have a shape elongated in the X direction, and the gate length direction of the amplifier transistor M3 may be parallel to the X direction. In any case, it is desirable that the gate electrode of the reset transistor M2, the node FD, the gate electrode of the capacitance switching transistor M5, and the gate electrode of the amplifier transistor M3 be arranged so as to be aligned in the X direction as in the previous embodiments.

The active regions 130A and 130B have a rectangular shape elongated in the Y direction and are arranged side by side in the Y direction so as to sandwich the active region 128 therebetween. The select transistor M41 is provided in the active region 130A so that the gate length direction thereof is parallel to the Y direction. Similarly, the select transistor M42 is provided in the active region 130B so that the gate length direction thereof is parallel to the Y direction. That is, the gate electrode of the select transistor M41, the gate electrode of the amplifier transistor M3, and the gate electrode of the select transistor M42 are arranged in this order in the Y direction.

The source region of the amplifier transistor M3 is electrically connected to the interconnection 152 via the contact plug 148. The drain region of the select transistor M41 is electrically connected to the interconnection 152 via the contact plug 150A. The drain region of the select transistor M42 is electrically connected to the interconnection 152 via the contact plug 150B. Thus, the source region of the amplifier transistor M3 is electrically connected to the drain region of the select transistor M41 and the drain region of the select transistor M42 via the interconnection 152. The source region of the select transistor M41 is electrically connected to the signal line 16A via the contact plug 144A. The source region of the select transistor M42 is electrically connected to the signal line 16B via the contact plug 144B.

In the present embodiment, the gate electrodes of the select transistors M41 and M42 are arranged so as to face the photoelectric conversion units PDB and PDA, respectively. Therefore, when the select transistors M41 and M42 are turned on, the dark current flowing into the photoelectric conversion units PDB and PDA may increase. However, the gate electrode of the select transistor M41 and the gate electrode of the select transistor M42 are arranged at symmetrical positions with respect to the amplifier transistor M3. Therefore, the influence on the photoelectric conversion unit PDB during the operation of the select transistor M41 is equal to the influence on the photoelectric conversion unit PDA during the operation of the select transistor M42. Therefore, it is possible to reduce the stripe-shaped fixed pattern noise superimposed on the captured image according to the driving of the select transistors M41 and M42.

As described above, according to the present embodiment, the same effects as those of the first to third embodiments may be obtained, and the stripe-shaped fixed pattern noise superimposed on the captured image may be reduced.

### Fifth Embodiment

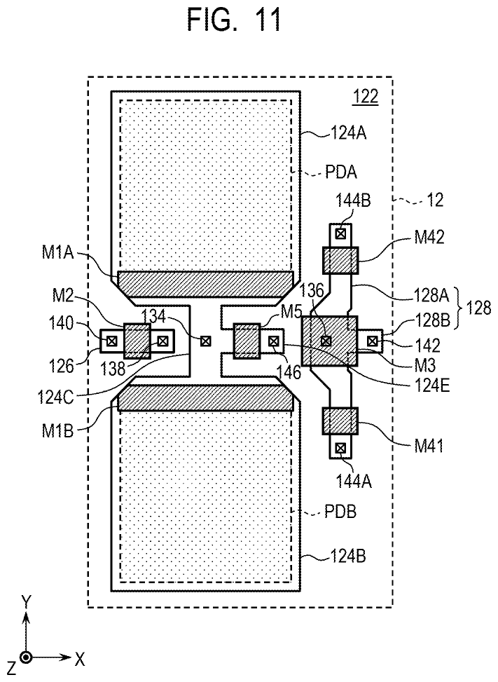

A photoelectric conversion device according to a fifth embodiment will be described with reference to FIG. 11. The same components as those of the photoelectric conversion devices according to the first to fourth embodiments are denoted by the same reference numerals, and description thereof will be omitted or simplified.

The photoelectric conversion device according to the present embodiment is the same as the photoelectric conversion device according to the fourth embodiment except that the configuration of the pixel 12 is different. In the present embodiment, differences from the photoelectric conversion device according to the fourth embodiment will be mainly described, and description of points similar to those of the photoelectric conversion devices according to the first to fourth embodiments will be appropriately omitted.

Similarly to FIG. 4, FIG. 11 is a plan view of the semiconductor layer (semiconductor substrate) in which each element constituting the pixel circuit is provided, as viewed from the front face side. In the fourth embodiment, the amplifier transistor M3 and the select transistors M41 and M42 are arranged in different active regions. On the other hand, in the present embodiment, the amplifier transistor M3 is configured to have one drain region and two source regions, so that the amplifier transistor M3 and the select transistors M41 and M42 are arranged in one active region 128. The arrangement of the other elements may be the same as that of the pixel 12 of the fourth embodiment.

The active region 128 has a first portion 128A extending in the Y direction and arranged adjacent to the active regions 124A and 124B in the X direction, and a second portion 128B extending in the X direction from a central portion of the first portion. The gate electrode of the amplifier transistor M3 is arranged at the center of the first portion 128A. The gate electrodes of the select transistors M41 and M42 are respectively arranged at upper and lower portions of the first portion 128A so that the gate electrode of the amplifier transistor M3 is located therebetween. A region of the first portion 128A between the gate electrode of the amplifier transistor M3 and the gate electrode of the select transistor M41 corresponds to the first source region of the amplifier transistor M3 and the drain region of the select transistor M41. A region of the first portion 128A between the gate electrode of the amplifier transistor M3 and the gate electrode of the select transistor M42 corresponds to the second source region of the amplifier transistor M3 and the drain region of the select transistor M42. The second portion 128B corresponds to the drain region of the amplifier transistor M3.

This configuration eliminates the need for the interconnection 152 that connects the source region of the amplifier transistor M3, the drain region of the select transistor M41, and the drain region of the select transistor M42. Accordingly, it is possible to reduce the interconnection density in the pixel 12, to reduce the possibility of occurrence of a defect such as an unintended short circuit between interconnections at the time of interconnection processing, and to improve the manufacturing yield.

As described above, according to the present embodiment, the same effects as those of the first to fourth embodiments may be obtained, and the manufacturing yield of the photoelectric conversion device may be improved.

### Sixth Embodiment

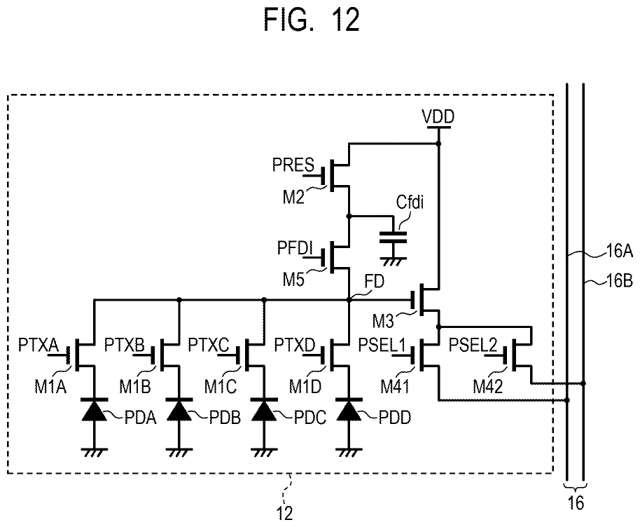

A photoelectric conversion device according to a sixth embodiment will be described with reference to FIG. 12 to FIG. 14. The same components as those of the photoelectric conversion devices according to the first to fifth embodiments are denoted by the same reference numerals, and description thereof will be omitted or simplified.

The photoelectric conversion device according to the present embodiment is the same as the photoelectric conversion device according to the first to fifth embodiments except that the configuration of the pixel 12 is different. In the present embodiment, differences from the photoelectric conversion devices according to the first to fifth embodiments will be mainly described, and description of points similar to those of the photoelectric conversion devices according to the first to fifth embodiments will be appropriately omitted.

FIG. 12 is an equivalent circuit diagram illustrating a configuration example of the pixel 12 in the photoelectric conversion device according to the present embodiment. Each of the pixels 12 of the fourth and fifth embodiments includes two sets of photoelectric conversion units PD and transfer transistors M1 sharing the node FD, the capacitance switching transistor M5, the reset transistor M2, the amplifier transistor M3, and the select transistors M41 and M42. On the other hand, as illustrated in FIG. 12, the pixel 12 of the present embodiment includes four sets of photoelectric conversion units PD and transfer transistors M1 that share the node FD, the capacitance switching transistor M5, the reset transistor M2, the amplifier transistor M3, and the select transistors M41 and M42. That is, the pixel 12 of the present embodiment further includes photoelectric conversion units PDC and PDD and transfer transistors M1C and M1D in addition to the pixel 12 of the fourth or fifth embodiment.

The photoelectric conversion unit PDC has an anode connected to the ground voltage node and a cathode connected to a source of the transfer transistor M1C. The photoelectric conversion unit PDD has an anode connected to the ground voltage node and a cathode connected to a source of the transfer transistor M1D. Drains of the transfer transistors M1C and M1D are connected to the drains of the transfer transistors M1A and M1B, the source of the capacitance switching transistor M5, and the gate electrode of the amplifier transistor M3. A node to which the drains of the transfer transistors M1A, M1B, M1C, and M1D, the source of the capacitance switching transistor M5, and the gate electrode of the amplifier transistor M3 are connected is the node FD.

In the case of the pixel configuration of the present embodiment, the control line 14 of each row may be constituted by a total of eight signal lines further including a signal line for supplying the control signal PTXC to the transfer transistor M1C and a signal line for supplying the control signal PTXD to the transfer transistor M1D. When the transfer transistors M1C and M1D are formed of n-channel transistors, they are turned on when the control signals PTXC and PTXD of high-level are supplied and are turned off when the control signals PTXC and PTXD of low-level are supplied. Other circuit configurations of the pixel 12 of the present embodiment may be the same as those of the pixel 12 of the fourth or fifth embodiment.

It may be also considered that the pixel circuit of FIG. 12 includes the pixel 12 including the photoelectric conversion units PDA and PDB and the transfer transistors M1A and M1B, and the pixel 12 including the photoelectric conversion units PDC and PDD and the transfer transistors M1C and M1D. In this case, the two pixels 12 share one set of the node FD, the capacitance switching transistor M5, the reset transistor M2, the amplifier transistor M3, and the select transistors M41 and M42. By applying such a configuration, it is possible to further reduce the number of transistors per photoelectric conversion unit PD in the pixel 12 (a ratio of the number of transistors to the number of photoelectric conversion units PD) as compared with the first to fifth embodiments, and it is possible to miniaturize the pixel 12, for example.

In the following description, it is assumed that the pixel 12 including the photoelectric conversion units PDA and PDB and the transfer transistors M1A and M1B and the pixel 12 including the photoelectric conversion units PDC and PDD and the transfer transistors M1C and M1D are arranged in adjacent rows of the same column. In the following description, it is also assumed that the photoelectric conversion units PDA and PDB share one microlens and the photoelectric conversion units PDC and PDD share another microlens.

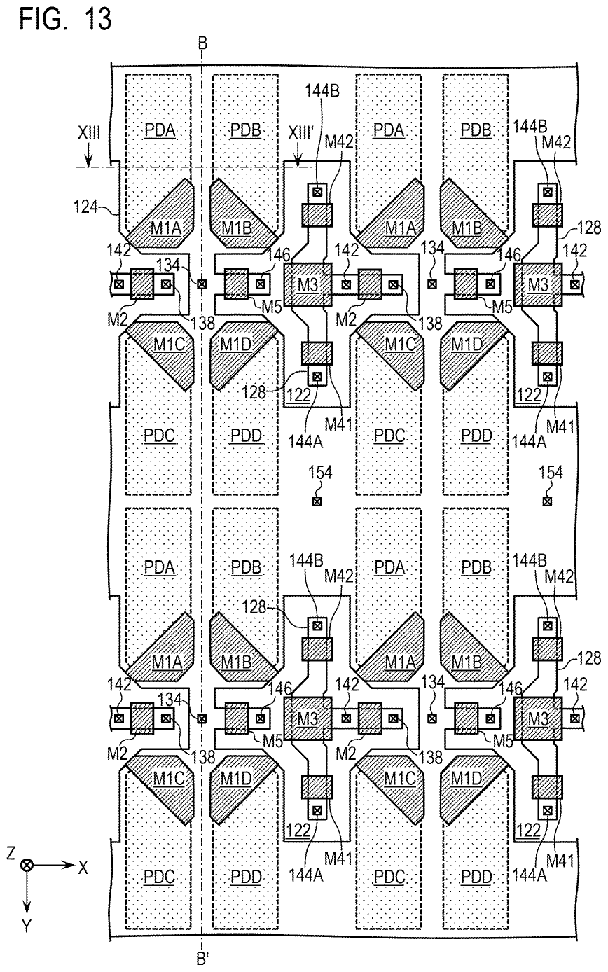

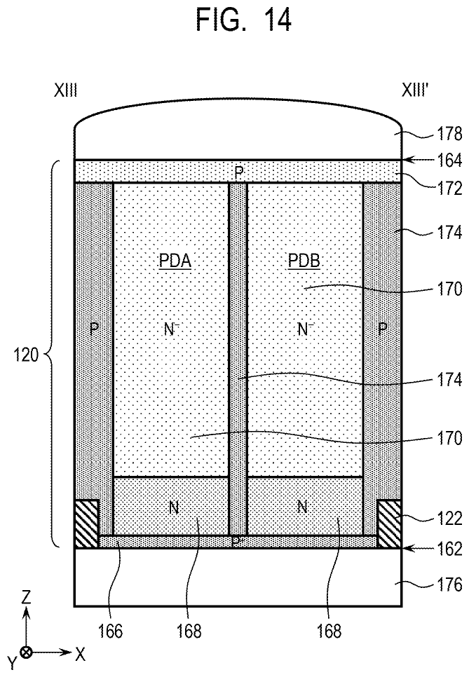

Next, the structure of the pixel 12 in the photoelectric conversion device according to the present embodiment will be described more specifically with reference to FIG. 13 and FIG. 14 by taking a back-illuminated photoelectric conversion device as an example. Although an example in which the configuration of the present embodiment is applied to a back-illuminated photoelectric conversion device will be described here, the configuration of the present embodiment may also be applied to a front-illuminated photoelectric conversion device.

Similarly to FIG. 4, FIG. 13 is a plan view of the semiconductor layer (semiconductor substrate) provided with each element constituting the pixel circuit as viewed from the front face side. The layout illustrated in FIG. 13 is basically the same as the layout of the fifth embodiment except that the photoelectric conversion unit PD and the transfer transistor M1 are divided into two parts in the X direction. That is, the photoelectric conversion unit PDA and the transfer transistor M1A in FIG. 11 are divided into two in the X direction correspond to the photoelectric conversion units PDA and PDB and the transfer transistors M1A and M1B in FIG. 13. The photoelectric conversion unit PDA and the transfer transistor M1A and the photoelectric conversion unit PDB and the transfer transistor M1B are arranged line-symmetrically with respect to an imaginary straight line B-B′ extending in the Y direction as an axis of symmetry. The photoelectric conversion unit PDB and the transfer transistor M1B in FIG. 11 divided into two in the X direction correspond to the photoelectric conversion units PDC and PDD and the transfer transistors M1C and M1D in FIG. 13. The photoelectric conversion unit PDC and the transfer transistor M1C and the photoelectric conversion unit PDD and the transfer transistor M1D are arranged line-symmetrically with respect to the straight line B-B′.

By arranging the photoelectric conversion units PDA and PDB in this manner and configuring the photoelectric conversion units PDA and PDB to share one microlens, it is possible to perform phase difference detection in the X direction based on a signal based on charges generated by the photoelectric conversion units PDA and PDB. By adding the signal based on the charge generated by the photoelectric conversion unit PDA and the signal based on the charge generated by the photoelectric conversion unit PDA, the imaging signal may be acquired. In a case where the photoelectric conversion units PDC and PDD are also configured to share another microlens, phase difference detection in the X direction may be performed based on a signal based on charges generated by the photoelectric conversion units PDC and PDD. By adding the signal based on the charge generated by the photoelectric conversion unit PDC and the signal based on the charge generated by the photoelectric conversion unit PDD, the imaging signal may be acquired.

In the layout of FIG. 13, since the drain region of the reset transistor M2 to which the voltage VDD is supplied and the drain region of the amplifier transistor M3 are shared, the active regions 126 and 128 of FIG. 11 are one active region 128 in FIG. 13. This layout has advantages of reducing the areas of the drain regions of the reset transistor M2 and the amplifier transistor M3 and reducing one contact plug. In addition, the reference voltage (ground voltage) supplied to the p-type semiconductor region 174 constituting the anodes of the photoelectric conversion units PDA, PDB, PDC, and PDD may be supplied via, for example, the contact plug 154.

FIG. 14 is a schematic cross-sectional view illustrating the structure of the photoelectric conversion units PDA and PDB that corresponds to, for example, a cross-sectional view taken along line XIII-XIII′ of FIG. 13. FIG. 14 illustrates only the photoelectric conversion units PDA and PDB, but the same applies to the photoelectric conversion units PDC and PDD.

The semiconductor layer 120 provided with the photoelectric conversion units PDA, PDB, PDC, and PDD has a first face 162 on the front face side and a second face 164 on the back face side. The semiconductor layer 120 includes p-type semiconductor regions 166, 172, and 174, n-type semiconductor regions 168 and 170, and an insulator isolation portion 122.

The n-type semiconductor regions 168 and 170 function as cathodes of photodiodes constituting the photoelectric conversion units PDA and PDB. The n-type semiconductor region 168 is arranged on a side of the first face 162 of the semiconductor layer 120, and the n-type semiconductor region 170 is arranged on a side of the second face 164 of the semiconductor layer 120. The n-type semiconductor region 170 serves as a photoelectric conversion region, and the n-type semiconductor region 168 serves to collect signal charge generated in the n-type semiconductor region 170. For these purposes, the peak impurity concentration of the n-type semiconductor region 168 is set higher than the peak impurity concentration of the n-type semiconductor region 170. The p-type semiconductor region 174 is provided on side faces of the n-type semiconductor regions 168 and 170. The p-type semiconductor region 174 constitutes anodes of photodiodes constituting the photoelectric conversion units PDA, PDB, PDC, and PDD, and also has a role of isolating adjacent photoelectric conversion units PDA, PDB, PDC, and PDD.

The p-type semiconductor region 166 is provided in contact with the first face 162 of the semiconductor layer 120. The p-type semiconductor region 172 is provided in contact with the second face 164 of the semiconductor layer 120. The p-type semiconductor regions 166 and 172 have a function of suppressing a dark current generated on the first face 162 and the second face 164, respectively. The peak impurity concentration of the p-type semiconductor region 166 is set higher than the peak impurity concentration of the p-type semiconductor region 172. The insulator isolation portion 122 is provided in the surface portion of the first face 162 of the semiconductor layer 120 and has a role of isolating the transistors and the photoelectric conversion units PDA, PDB, PDC, and PDD from each other. The insulator isolation portion 122 is surrounded by the p-type semiconductor regions 166 and 174.

An optical structure layer 178 including the color filters, the microlenses, and the like is provided over the second face 164 of the semiconductor layer 120. An interconnection structure layer 176 including a gate layer constituting the gate electrodes of the transistors and metal interconnection layers is provided over a side of the first face 162 of the semiconductor layer 120. A circuit substrate 180 and a support substrate (both not illustrated) may be further provided on the side of the first face 162 of the semiconductor layer 120.

In a case where the back-illuminated photoelectric conversion device is configured as in the present embodiment, the interconnection structure layer 176 is not arranged over the second face 164 which is the light-receiving surface of the semiconductor layer 120. Therefore, it is possible to prevent the light incident on the photoelectric conversion device from being blocked by the interconnection constituting the interconnection structure layer 176, and it is possible to improve the light receiving efficiency in the photoelectric conversion units PDA, PDB, PDC, and PDD.

As described above, according to the present embodiment, the same effects as those of the first to fifth embodiments may be obtained, and miniaturization of the pixel 12 and improvement in sensitivity may be realized.

### Seventh Embodiment

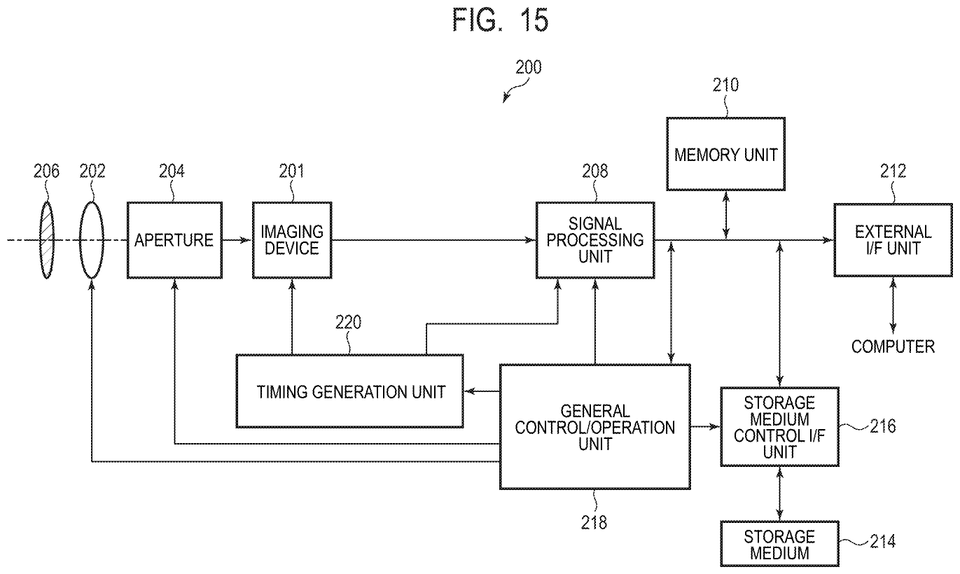

A photoelectric conversion system according to a seventh embodiment will be described with reference to FIG. 15. FIG. 15 is a block diagram illustrating a schematic configuration of a photoelectric conversion system according to the present embodiment.

The photoelectric conversion device 100 described in the first to sixth embodiments may be applied to various photoelectric conversion systems. Examples of applicable photoelectric conversion systems include digital still cameras, digital camcorders, surveillance cameras, copying machines, facsimiles, mobile phones, on-vehicle cameras, observation satellites, and the like. A camera module including an optical system such as a lens and an imaging device is also included in the photoelectric conversion system. FIG. 15 exemplifies a block diagram of a digital still camera as one of these.

The photoelectric conversion system 200 illustrated in FIG. 15 includes an imaging device 201, a lens 202 that forms an optical image of an object on the imaging device 201, an aperture 204 that changes the amount of light passing through the lens 202, and a barrier 206 that protects the lens 202. The lens 202 and the aperture 204 constitute an optical system that focuses light onto the imaging device 201. The imaging device 201 is the photoelectric conversion device 100 described in any of the first to sixth embodiments, and converts the optical image formed by the lens 202 into image data.

The photoelectric conversion system 200 further includes a signal processing unit 208 that processes an output signal output from the imaging device 201. The signal processing unit 208 generates image data from the digital signal output from the imaging device 201. Further, the signal processing unit 208 performs various corrections and compressions as necessary and outputs the processed image data. The imaging device 201 may include an AD conversion unit that generates a digital signal to be processed by the signal processing unit 208. The AD conversion unit may be formed on a semiconductor layer (semiconductor substrate) on which the photoelectric conversion unit of the imaging device 201 is formed or may be formed on a semiconductor layer (semiconductor substrate) different from the semiconductor layer on which the photoelectric conversion unit of the imaging device 201 is formed. The signal processing unit 208 may be formed on the same semiconductor layer as the imaging device 201.

The photoelectric conversion system 200 further includes a memory unit 210 for temporarily storing image data and an external interface unit (external I/F unit) 212 for communicating with an external computer or the like. The photoelectric conversion system 200 further includes a storage medium 214 such as a semiconductor memory for performing storing or reading out of imaging data, and a storage medium control interface unit (storage medium control I/F unit) 216 for performing storing on or reading out from the storage medium 214. The storage medium 214 may be built in the photoelectric conversion system 200 or may be detachable.

The photoelectric conversion system 200 further includes a general control/operation unit 218 that performs various calculations and controls the entire digital still camera, and a timing generation unit 220 that outputs various timing signals to the imaging device 201 and the signal processing unit 208. Here, the timing signal or the like may be input from the outside, and the photoelectric conversion system 200 may include at least the imaging device 201 and the signal processing unit 208 that processes the output signal output from the imaging device 201.

The imaging device 201 outputs an imaging signal to the signal processing unit 208. The signal processing unit 208 performs predetermined signal processing on the imaging signal output from the imaging device 201 and outputs the processed image data. The signal processing unit 208 generates an image using the imaging signal.

As described above, according to the present embodiment, it is possible to realize a photoelectric conversion system to which the photoelectric conversion device 100 according to any of the first to sixth embodiments is applied.

### Eighth Embodiment

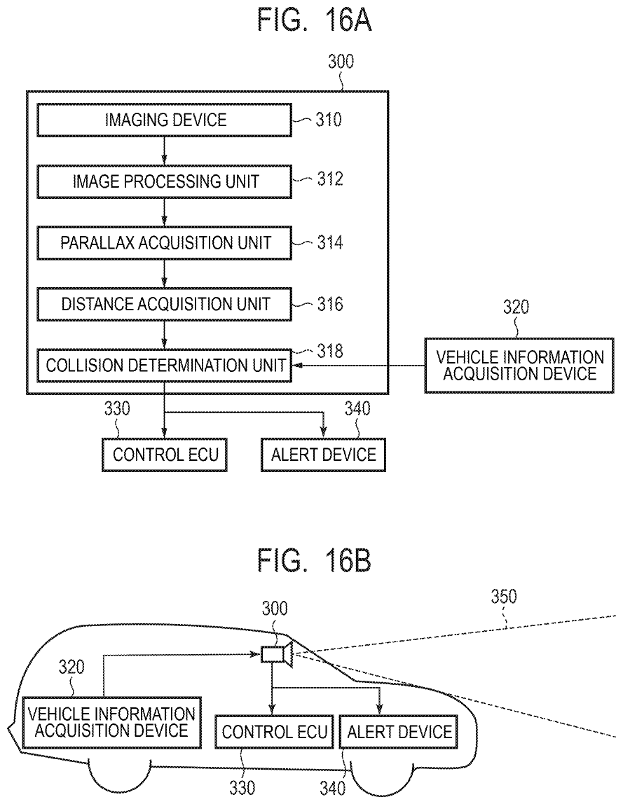

The photoelectric conversion system and a movable object according to an eighth embodiment will be described with reference to FIG. 16A and FIG. 16B. FIG. 16A is a diagram illustrating a configuration of a photoelectric conversion system according to the present embodiment. FIG. 16B is a diagram illustrating a configuration of a movable object according to the present embodiment.

FIG. 16A illustrates an example of a photoelectric conversion system related to an on-vehicle camera. The photoelectric conversion system 300 includes an imaging device 310. The imaging device 310 is the photoelectric conversion device 100 according to any one of the first to sixth embodiments. The photoelectric conversion system 300 includes an image processing unit 312 that performs image processing on a plurality of image data acquired by the imaging device 310, and a parallax acquisition unit 314 that calculates parallax (phase difference of parallax images) from the plurality of image data acquired by the imaging device 310. The photoelectric conversion system 300 further includes a distance acquisition unit 316 that calculates a distance to an object based on the calculated parallax, and a collision determination unit 318 that determines whether there is a collision possibility based on the calculated distance. Here, the parallax acquisition unit 314 and the distance acquisition unit 316 are an example of a distance information acquisition unit that acquires distance information to the object. That is, the distance information is information related to a parallax, a defocus amount, a distance to the object, and the like. The collision determination unit 318 may determine the collision possibility using any of the distance information. The distance information acquisition unit may be realized by dedicatedly designed hardware or may be realized by a software module. Further, it may be realized by a field programmable gate array (FPGA), an application specific integrated circuit (ASIC), or the like, or may be realized by a combination of these.

The photoelectric conversion system 300 is connected to a vehicle information acquisition device 320 and may acquire vehicle information such as a vehicle speed, a yaw rate, and a steering angle. Further, the photoelectric conversion system 300 is connected to a control ECU 330 which is a control device that outputs a control signal for generating a braking force to the vehicle based on the determination result of the collision determination unit 318. The photoelectric conversion system 300 is also connected to an alert device 340 that issues an alert to the driver based on the determination result of the collision determination unit 318. For example, when the determination result of the collision determination unit 318 indicates that the possibility of collision is high, the control ECU 330 performs vehicle control to avoid collision and reduce damage by, for example, applying a brake, returning an accelerator, or suppressing engine output. The alert device 340 gives an alert to the user by sounding an alarm such as a sound, displaying alert information on a screen of a car navigation system or the like, giving vibration to a seat belt or a steering wheel, or the like.

In the present embodiment, an image of the surroundings of the vehicle, for example, the front or the rear is captured by the photoelectric conversion system 300. FIG. 16B illustrates the photoelectric conversion system in the case of capturing an image in front of the vehicle (imaging range 350). The vehicle information acquisition device 320 sends instructions to the photoelectric conversion system 300 or the imaging device 310. With such a configuration, the accuracy of distance measurement may be further improved.

Although an example in which control is performed so as not to collide with another vehicle has been described above, the present embodiment is also applicable to control in which automatic driving is performed so as to follow another vehicle, control in which automatic driving is performed so as not to protrude from a lane, and the like. Further, the photoelectric conversion system is not limited to a vehicle such as an own vehicle, and may be applied to, for example, other mobile objects (mobile devices), such as, for example, a ship, an aircraft, or an industrial robot. In addition, the present embodiment is not limited to the movable object and may be widely applied to equipment using object recognition, such as intelligent transport systems (ITS).

### Ninth Embodiment

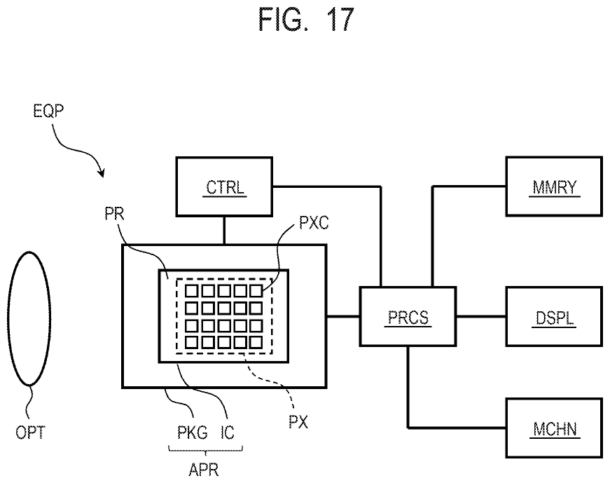

An equipment according to a ninth embodiment will be described with reference to FIG. 17. FIG. 17 is a block diagram illustrating a schematic configuration of an equipment according to the present embodiment.

FIG. 17 is a schematic diagram illustrating an equipment EQP including a photoelectric conversion device APR. The photoelectric conversion device APR has the function of the photoelectric conversion device 100 according to any of the first to sixth embodiments. All or part of the photoelectric conversion device APR is a semiconductor device IC. The photoelectric conversion device APR of the present example may be used as, for example, an image sensor, an auto focus (AF) sensor, a photometric sensor, or a distance measuring sensor. The semiconductor device IC includes a pixel region PX in which pixel circuits PXC each including a photoelectric conversion unit are arranged in a matrix. The semiconductor device IC may include a peripheral region PR around the pixel region PX. A circuit other than the pixel circuit may be arranged in the peripheral region PR.

The photoelectric conversion device APR may have a structure (chip stacked structure) in which a first semiconductor chip provided with a plurality of photoelectric conversion units and a second semiconductor chip provided with peripheral circuits are stacked. Each of the peripheral circuits on the second semiconductor chip may be column circuits corresponding to pixel columns of the first semiconductor chip. The peripheral circuits on the second semiconductor chip may be matrix circuits corresponding to pixels or pixel blocks on the first semiconductor chip. As the connection between the first semiconductor chip and the second semiconductor chip, a through electrode (through silicon via (TSV)), an inter-chip interconnection by direct bonding of a conductor such as copper, a connection by a micro bump between the chips, a connection by wire bonding, or the like may be employed.

The photoelectric conversion device APR may include a package PKG that accommodates the semiconductor device IC in addition to the semiconductor device IC. The package PKG may include a base body to which the semiconductor device IC is fixed, a lid body such as glass facing the semiconductor device IC, and connection members such as bonding wires or bumps for connecting terminals provided on the base body and terminals provided on the semiconductor device IC.

The equipment EQP may further include at least one of an optical device OPT, a control device CTRL, a processing device PRCS, a display device DSPL, a storage device MMRY, and a mechanical device MCHN. The optical device OPT corresponds to the photoelectric conversion device APR, and is, for example, a lens, a shutter, or a mirror. The control device CTRL controls the photoelectric conversion device APR and is, for example, a semiconductor device such as an ASIC. The processing device PRCS processes a signal output from the photoelectric conversion device APR and constitutes an analog front end (AFE) or a digital front end (DFE). The processing device PRCS is a semiconductor device such as a central processing unit (CPU) or an ASIC. The display device DSPL may be an electroluminescent (EL) display device or a liquid crystal display device that displays information (image) obtained by the photoelectric conversion device APR. The storage device MMRY may be a magnetic device or a semiconductor device that stores information (image) obtained by the photoelectric conversion device APR. The storage device MMRY may be a volatile memory such as an SRAM or a DRAM, or a nonvolatile memory such as a flash memory or a hard disk drive. The mechanical device MCHN may include a movable portion or a propulsion portion such as a motor or an engine. In the equipment EQP, a signal output from the photoelectric conversion device APR is displayed on the display device DSPL or transmitted to the outside by a communication device (not illustrated) included in the equipment EQP. Therefore, it is preferable that the equipment EQP further includes a storage device MMRY and a processing device PRCS separately from the storage circuit unit and the arithmetic circuit unit included in the photoelectric conversion device APR.

The equipment EQP illustrated in FIG. 17 may be an electronic device such as an information terminal (for example, a smartphone or a wearable terminal) having a photographing function or a camera (for example, an interchangeable lens camera, a compact camera, a video camera, and a monitoring camera). The mechanical device MCHN in the camera may drive components of the optical device OPT for zooming, focusing, and shutter operation. The equipment EQP may be a transportation device (movable object) such as a vehicle, a ship, or an aircraft. The equipment EQP may be a medical device such as an endoscope or a computed tomography (CT) scanner.

The mechanical device MCHN in the transportation device may be used as a mobile device. The equipment EQP as a transportation device is suitable for transporting the photoelectric conversion device APR, or for assisting and/or automating operation (manipulation) by an imaging function. The processing device PRCS for assisting and/or automating driving (manipulation) may perform processing for operating the mechanical device MCHN as a mobile device based on information obtained by the photoelectric conversion device APR.

The photoelectric conversion device APR according to the present embodiment may provide a high value to a designer, a manufacturer, a seller, a purchaser, and/or a user thereof. Therefore, when the photoelectric conversion device APR is mounted on the equipment EQP, the value of the equipment EQP may also be increased. Therefore, in manufacturing and selling the equipment EQP, it is advantageous to determine the mounting of the photoelectric conversion device APR of the present embodiment on the equipment EQP in order to increase the value of the equipment EQP.

### Modified Embodiments

The present disclosure is not limited to the above embodiments, and various modifications are possible.

For example, an example in which a part of the configuration of any of the embodiments is added to another embodiment or an example in which a part of the configurations of any of the embodiments is substituted with some of the configurations of another embodiment is also an embodiment of the present disclosure.

The circuit configurations of the pixels 12 illustrated in FIG. 3, FIG. 7, FIG. 9, and FIG. 12 are examples, and may be appropriately changed. For example, the number of photoelectric conversion units PD included in each pixel 12 is not limited to two or four. Alternatively, a plurality of capacitance switching transistors M5 may be provided so that the capacitance value of the capacitor coupled to the node FD may be switched to a plurality of values.

The photoelectric conversion systems described in the seventh and eighth embodiments are examples of photoelectric conversion systems to which the photoelectric conversion device of the present disclosure may be applied, and the photoelectric conversion system to which the photoelectric conversion device of the present disclosure may be applied is not limited to the configurations illustrated in FIG. 15 and FIG. 16A.

According to the present disclosure, in a photoelectric conversion device in which some elements of a pixel circuit are shared by a plurality of pixels, it is possible to reduce the influence of noise generated due to driving of transistors configuring the pixel circuit.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-068332, filed Apr. 17, 2025, which is hereby incorporated by reference herein in its entirety.

1. A photoelectric conversion device comprising:
a first photoelectric conversion unit and a second photoelectric conversion unit each configured to generate charge according to incidence of light;
a first transistor configured to transfer charge held by the first photoelectric conversion unit to a first node;
a second transistor configured to transfer charge held by the second photoelectric conversion unit to the first node;
a third transistor configured to reset a voltage of the first node; and
a fourth transistor configured to switch a capacitance value of a capacitor coupled to the first node,
wherein a gate electrode of the first transistor is arranged between the first photoelectric conversion unit and a gate electrode of the third transistor,
wherein a gate electrode of the second transistor is arranged between the second photoelectric conversion unit and the gate electrode of the third transistor,
wherein the gate electrode of the third transistor faces the gate electrode of the first transistor and the gate electrode of the second transistor,
wherein the gate electrode of the first transistor is arranged between the first photoelectric conversion unit and a gate electrode of the fourth transistor,
wherein the gate electrode of the second transistor is arranged between the second photoelectric conversion unit and the gate electrode of the fourth transistor, and
wherein the gate electrode of the fourth transistor faces the gate electrode of the first transistor and the gate electrode of the second transistor.

2. The photoelectric conversion device according to claim 1,
wherein the gate electrode of the first transistor and the gate electrode of the second transistor are arranged line-symmetrically with respect to a first straight line extending in a first direction as a symmetry axis in a plan view, and
wherein the gate electrode of the third transistor is arranged so as to overlap the first straight line in the plan view.

3. The photoelectric conversion device according to claim 1,
wherein the gate electrode of the first transistor and the gate electrode of the second transistor are arranged line-symmetrically with respect to a first straight line extending in a first direction as a symmetry axis in a plan view, and
wherein the gate electrode of the fourth transistor is arranged so as to overlap the first straight line in the plan view.

4. The photoelectric conversion device according to claim 2, further comprising: a fifth transistor configured to output a signal according to a voltage of the first node,
wherein a gate electrode of the fifth transistor is arranged so as to overlap the first straight line and not overlap a region between the gate electrode of the first transistor and the gate electrode of the second transistor in the plan view.

5. The photoelectric conversion device according to claim 4, further comprising: a sixth transistor configured to output an output signal of the fifth transistor to a first output line; and a seventh transistor configured to output an output signal of the fifth transistor to a second output line,
wherein a gate electrode of the sixth transistor faces the first photoelectric conversion unit, and
wherein a gate electrode of the seventh transistor faces the second photoelectric conversion unit.

6. The photoelectric conversion device according to claim 5, wherein the gate electrode of the sixth transistor, the gate electrode of the fifth transistor, and the gate electrode of the seventh transistor are arranged in this order along a second direction intersecting the first direction.

7. The photoelectric conversion device according to claim 1, further comprising: an insulator isolation portion provided on a first face of a semiconductor layer, wherein the insulator isolation portion defines a first active region in which the first photoelectric conversion unit and the first transistor are arranged, a second active region in which the second photoelectric conversion unit and the second transistor are arranged, and a third active region in which the third transistor is arranged.

8. The photoelectric conversion device according to claim 7, wherein the first active region and the second active region are independent of each other.

9. The photoelectric conversion device according to claim 7, wherein the first active region and the second active region constitute one continuous active region.

10. The photoelectric conversion device according to claim 7, wherein the first photoelectric conversion unit and the second photoelectric conversion unit are configured to receive light from a side of the first face.

11. The photoelectric conversion device according to claim 7, wherein the first photoelectric conversion unit and the second photoelectric conversion unit are configured to receive light from a side of a second face opposite to the first face.

12. The photoelectric conversion device according to claim 5, wherein the fifth transistor, the sixth transistor, and the seventh transistor are arranged in different active regions.

13. The photoelectric conversion device according to claim 5, wherein the fifth transistor, the sixth transistor, and the seventh transistor are arranged in the same active region.

14. The photoelectric conversion device according to claim 4, wherein the third transistor and the fifth transistor are arranged in the same active region.

15. The photoelectric conversion device according to claim 1, further comprising:
a third photoelectric conversion unit and a fourth photoelectric conversion unit each configured to generate charge according to incidence of light;
an eighth transistor configured to transfer charge held by the third photoelectric conversion unit to the first node;
a ninth transistor configured to transfer charge held by the fourth photoelectric conversion unit to the first node;
a first microlens shared by the first photoelectric conversion unit and the third photoelectric conversion unit; and
a second microlens shared by the second photoelectric conversion unit and the fourth photoelectric conversion unit.

16. The photoelectric conversion device according to claim 15,
wherein the first photoelectric conversion unit and the first transistor, and the third photoelectric conversion unit and the eighth transistor are arranged line-symmetrically with respect to a second straight line extending in a second direction as an axis of symmetry, and
wherein the second photoelectric conversion unit and the second transistor, and the fourth photoelectric conversion unit and the ninth transistor are arranged line-symmetrically with respect to the second straight line as an axis of symmetry.

17. A photoelectric conversion device comprising:
an insulator isolation portion defining a plurality of active regions in a first face of a semiconductor layer;
a first photoelectric conversion unit arranged in a first active region of the plurality of active regions and configured to generate charge according to incidence of light;
a second photoelectric conversion unit arranged in a second active region of the plurality of active regions and configured to generate charge according to incidence of light;
a first transistor arranged in the first active region and configured to transfer charge of the first photoelectric conversion unit to a first node;
a second transistor arranged in the second active region and configured to transfer charge of the second photoelectric conversion unit to the first node; and
a third transistor arranged in a third active region of the plurality of active regions and configured to reset a voltage of the first node,
wherein a gate electrode of the first transistor is arranged between the first photoelectric conversion unit and a gate electrode of the third transistor,
wherein a gate electrode of the second transistor is arranged between the second photoelectric conversion unit and the gate electrode of the third transistor, and
wherein the gate electrode of the third transistor faces the gate electrode of the first transistor and the gate electrode of the second transistor.

18. A photoelectric conversion system comprising:
the photoelectric conversion device according to claim 1; and
a signal processing device configured to process a signal output from the photoelectric conversion device.

19. A movable object comprising:
the photoelectric conversion device according to claim 1;
a distance information acquisition unit configured to acquire distance information to an object from a parallax image based on a signal from the photoelectric conversion device; and
a control unit configured to control the movable object based on the distance information.

20. An equipment comprising:
the photoelectric conversion device according to claim 1; and
at least one of
an optical device corresponding to the photoelectric conversion device,
a control device configured to control the photoelectric conversion device,
a processing device configured to process a signal output from the photoelectric conversion device,
a mechanical device that is controlled based on information obtained by the photoelectric conversion device,
a display device configured to display information obtained by the photoelectric conversion device, and
a storage device configured to store information obtained by the photoelectric conversion device.
